(19) United States
(12) Patent Application Publication
(10) Pub. No.: US 2019/0229548 A1
(43) Pub. Date: Jul. 25, 2019

(54) ELECTRONIC DEVICE AND CHARGING CONTROL METHOD THEREOF

(71) Applicant: SHENZHEN ROYOLE TECHNOLOGIES CO. LTD., Shenzhen, Guangdong (CN)

(72) Inventors: Linkai HUANG, Shenzhen, Guangdong (CN); Zegang YE, Shenzhen, Guangdong (CN)

(21) Appl. No.: 16/330,302

(22) PCT Filed: Dec. 12, 2016
(86) PCT No.: PCT/CN2016/109371

§ 371 Date: Mar. 4, 2019

(51) Int. Cl. H02J 7/00; G01R 31/3842; H01M 10/44; H01M 10/48; H01M 10/42

(52) U.S. Cl. CPC H02J 7/0077; H02J 7/0091; G01R 31/3842; H01M 2010/4278; H01M 10/486; H01M 10/425; H01M 2010/4271; H01M 10/443

(57) ABSTRACT

The present disclosure discloses a charging control method, applied to an electronic device. The method comprises: determining a resistance value of a charging path impedance circuit of a battery; obtaining charging current of a constant current charging stage when the battery is in the constant current charging stage; calculating a divided voltage of the charging path impedance circuit according to the resistance value and the charging current; and adjusting a constant voltage threshold voltage for triggering switching of the battery from the constant current charging stage to a constant voltage charging stage to be equal to a sum of an initial constant voltage threshold voltage and the divided voltage. The present disclosure also discloses the electronic device. The electronic device and the charging control method of the present disclosure, which can set the constant current charging stage longer in a allowable range and increase a charging speed.

### TECHNICAL FIELD

This present disclosure relates to an electronic device, and more particularly, to an electronic device with charging function and a charging control method thereof.

### BACKGROUND

Currently, electronic devices such as mobile phones, tablet computers, and head-mounted display devices have been used widely, which greatly facilitates and improves people's lives. Current electronic devices, usually equipped with a rechargeable battery, can be recycled. The battery of the electronic device now includes several charging stages, usually including pre-charging, constant current charging, constant voltage charging, and charging cutoff. Usually, in order to achieve fast charging, the constant current charging stage usually applies large current for constant current charging to quickly replenish the battery. Generally, the constant current charging stage stops when the voltage of the battery reaches a preset value, and switches to the constant voltage charging stage. However, in the prior art, the preset value is often set too low, resulting in premature transition from the constant current charging stage to the constant voltage charging stage, and failure to reach maximized charging speed.

### SUMMARY

Embodiments of the present disclosure disclose an electronic device and a charging control method thereof, which can prolong the constant current charging stage and improve a charging speed.

Embodiments of the present disclosure disclose an electronic device, which comprises a battery, a charging management chip, a charging path impedance circuit and a processor. The battery comprises a battery cell. The charging path impedance circuit is located between the battery cell and the charging management chip. Wherein, the processor is configured to determine a resistance value of the charging path impedance circuit, and obtain a charging current of a constant current charging stage when the battery is in the constant current charging stage, and calculate a divided voltage of the charging path impedance circuit according to the resistance value of the charging path impedance circuit and the charging current of the constant current charging stage. The processor is configured to adjust a constant voltage threshold voltage for triggering switching of the battery from the constant current charging stage to a constant voltage charging stage to be equal to a sum of an initial constant voltage threshold voltage and the divided voltage of the charging path impedance circuit.

Embodiments of the present disclosure disclose a charging control method, applied to an electronic device. The electronic device comprises a battery. The battery comprises a battery cell and a charging circuit. Wherein, the method comprises the steps of: determining a resistance value of a charging path impedance circuit of the battery; obtaining a charging current of a constant current charging stage when the battery is in the constant current charging stage; calculating a divided voltage of the charging path impedance circuit according to the resistance value of the charging path impedance circuit and the charging current of the constant current charging stage; and adjusting a constant voltage threshold voltage for triggering switching of the battery from the constant current charging stage to a constant voltage charging stage to be equal to a sum of an initial constant voltage threshold voltage and the divided voltage of the charging path impedance circuit.

The electronic device and the charging control method thereof of the present disclosure can increase a critical value from the constant current charging stage to the constant voltage charging stage within a reasonable range, prolong the constant current charging stage, and improve the charging speed.

### BRIEF DESCRIPTION OF THE ACCOMPANYING DRAWINGS

To describe technology solutions in the embodiments of the present disclosure more clearly, the following briefly introduces the accompanying drawings required for describing the embodiments. Obviously, the accompanying drawings in the following description show merely some embodiments of the present disclosure, those of ordinary skill in the art may also derive other obvious variations according to these accompanying drawings without creative efforts.

FIG. 1 is a structural block diagram of an electronic device according to one embodiment of the present disclosure.

FIG. 2 is a schematic diagram showing changes in voltage and current of a battery in each charging stage according to one embodiment of the present disclosure.

FIG. 3 is a flowchart of a charging control method in accordance with one embodiment of the present disclosure.

FIG. 4 is a sub-flowchart of step S301 in FIG. 3.

FIG. 5 is a flowchart of a charging control method in another embodiment of the present disclosure.

### DETAILED DESCRIPTION OF ILLUSTRATED EMBODIMENTS

The technical solution in the embodiments of the present disclosure will be described clearly and completely hereinafter with reference to the accompanying drawings in the embodiments of the present disclosure. Obviously, the described embodiments are merely some but not all the embodiments of the present disclosure. All other embodiments obtained by a person of ordinary skill in the art according to the embodiments of the present disclosure without creative efforts shall all fall within the protection scope of the present disclosure.

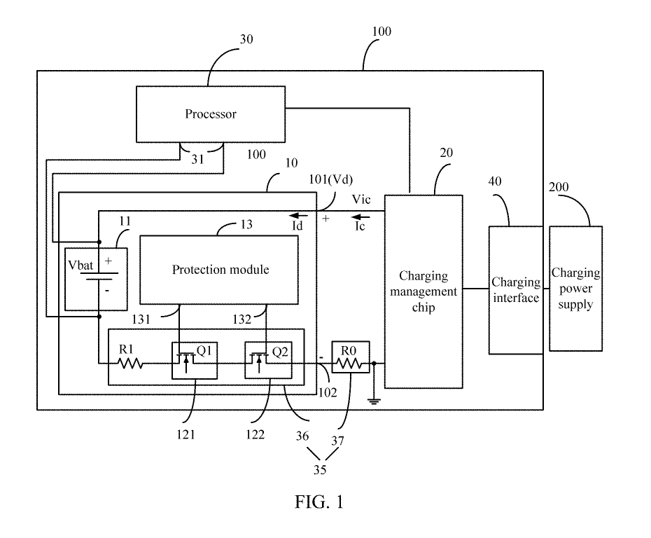

Referring to FIG. 1, a schematic diagram of an electronic device 100 according to one embodiment of the present disclosure is provided. As shown in FIG. 1, the electronic device 100 includes a battery 10, a charging management chip 20, a processor 30, a charging path impedance circuit 35 and a charging interface 40. The battery 10 includes a battery cell 11. The charging path impedance circuit 35 is the circuit with impedance, other than the battery cell 11, located between the charging management chip 20 and the battery 10.

The charging interface 40 is configured to be coupled to the charging power supply 200. When the charging interface 40 is coupled to the charging power supply 200, the charging management chip 20 is configured to convert a power supply voltage of the charging interface 40 into a corresponding charging voltage Vic or a charging current Ic to charge the battery 10. The charging management chip 20 detects a voltage Vd and a current Id of the battery 10 in real time, and switches charging stages of the battery 10 according to the detected voltage Vd and/or current Id of the battery 10. In some embodiments, the charging stages of the battery 10 at least includes a constant current charging stage and a constant voltage charging stage.

The processor 30 is coupled to the battery cell 11 and the power management chip 20. The processor 30 is configured to determine a resistance value Rbat of the charging path impedance circuit 35, obtain a charging current Ic of the constant current charging stage when the battery 10 is in the constant current charging stage, and calculate a divided voltage Vf of the charging path impedance circuit 35 according to the resistance value Rbat of the charging path impedance circuit 35 and the charging current Ic of the constant current charging stage. The processor 30 adjusts a constant voltage threshold voltage Vc for triggering switching from the constant current charging stage to the constant voltage charging stage to be equal to a sum of an initial constant voltage threshold voltage Vc1 and the divided voltage Vf of the charging path impedance circuit 35, that is, the constant voltage threshold voltage Vc is adjusted to be Vc=Vc1+Vf. Where, the processor 30 calculates the divided voltage Vf of the charging path impedance circuit 35 according to a formula: Vf=Rbat*Ic.

In some embodiments, the initial constant voltage threshold voltage Vc1 is 4.2V (volts) or 4.35V.

Since the adjusted constant voltage threshold voltage Vc for triggering switching from the constant current charging stage to the constant voltage charging stage is equal to the sum of the initial constant voltage threshold voltage Vc1 and the divided voltage Vf of the charging path impedance circuit 35, thereby effectively prolonging the constant current charging stage and increasing the charging speed.

The charging management chip 20 controls the battery 10 to switch from the constant current charging stage to the constant voltage charging stage when the battery 10 is in the constant current charging stage and the voltage Vd of the battery 10 reaches the adjusted constant voltage threshold voltage Vc. Where, the voltage Vd of the battery 10 refers to an overall voltage of the battery 10, including a sum of the voltages of the battery cell 11 and the charging circuit 12.

In some embodiments, the processor 30 determines the resistance value Rbat of the charging path impedance circuit 35 of the battery 10, specifically, the processor 30 obtains a current voltage Vbat of the battery cell 11 and the charging voltage Vic and the charging current Ic of the charging management chip 20 when the battery 10 is in a specific charging stage. The processor 30 calculates the resistance value Rbat of the charging path impedance circuit 35 according to the voltage Vbat of the battery cell 11 and the charging voltage Vic and the charging current Ic output by the charging management chip 20.

Specifically, the processor 30 calculates the resistance value Rbat of the charging path impedance circuit 35 according to the formula: Rbat=(Vic−Vbat)/Ic.

Where, the specific charging stage may be the constant current charging stage. In other embodiments, the specific charging stage may also be a pre-charging stage before the constant current charging stage or the constant voltage charging stage after the constant current charging stage. The processor 30 obtains the voltage Vbat of the battery cell 11, the charging voltage Vic and the charging current Ic output by the charging management chip 20 under a same moment. At the same moment, the voltage Vbat of the battery cell 11, the charging voltage Vic and the charging current Ic output by the charging management chip 20 are related to the resistance value Rbat of the charging path impedance circuit 35, and the resistance value Rbat of the charging path impedance circuit 35 can also be calculated according to the formula: Rbat=(Vic−Vbat)/Ic.

In some embodiments, the processor 30 re-determines the resistance value Rbat of the charging path impedance circuit 35 at the beginning of each charging. Then, during this charging process, the processor 30 obtains charging current Ic of the constant current charging stage when the battery 10 is determined to be in the constant current charging stage. As described above, the processor 30 calculates the divided voltage Vf of the charging path impedance circuit 35 according to the resistance value Rbat of the charging path impedance circuit 35 and the charging current Ic of the constant current charging stage, and adjusts the constant voltage threshold voltage for switching from the constant current charging stage to the constant voltage charging stage to be equal to the sum of the initial constant voltage threshold voltage and the divided voltage of the charging path impedance circuit. Therefore, since the resistance value Rbat of the charging path impedance circuit 35 may change with time and usage conditions, at the beginning of each charging, the resistance value Rbat of the charging path impedance circuit 35 is re-determined, which is more accurate.

In other embodiments, since the resistance value Rbat of the charging path impedance circuit 35, may change slowly with time, the resistance value Rbat is a relatively fixed value, the processor 30 may not renew the resistance value Rbat of the charging path impedance circuit 35 after determining the resistance value Rbat of the charging path impedance circuit 35. Alternatively, the processor 30 re-determines the resistance value Rbat of the charging path impedance circuit 35 at predetermined intervals (for example, ten days) or a predetermined number of charging times (for example, 20 times). After the processor 30 re-determines the resistance value Rbat of the charging path impedance 35, calculates the divided voltage Vf of the charging path impedance circuit 35 according to the resistance value Rbat of the charging path impedance circuit 35 and the charging current Ic of the constant current charging stage, and adjusts the constant voltage threshold voltage Vc for switching from the constant voltage charging stage to the constant voltage threshold voltage to be equal to the sum of the initial constant voltage threshold voltage Vc1 and the divided voltage Vf of the charging path impedance circuit 35. Thereby, the adjusted constant voltage threshold voltage Vc is determined again.

Where, the charging stages of the battery 10 include the aforementioned pre-charging stage, the constant current charging stage, the constant voltage charging stage, and a charging cutoff. The charging management chip 20 pre-stores a constant current threshold voltage V_{L} for triggering switching from the pre-charging stage to the constant current charging stage, and a constant voltage threshold voltage Vc1 for triggering switching from the constant current charging stage to the constant voltage charging stage, and a cutoff critical current Ij for triggering switching from the constant voltage charging stage to the charging cutoff. The charging management chip 20 replaces the constant voltage threshold voltage Vc1 with the adjusted constant voltage threshold voltage Vc in response to the control of the processor 30.

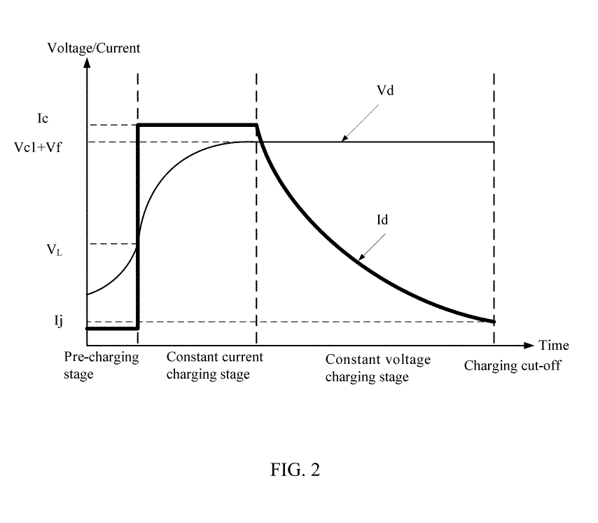

Referring further to FIG. 2, a schematic diagram of changes in voltage Vd and current Id of battery 10 at various charging stages is illustrated. Where, the charging management chip 20 controls the battery 10 to enter the pre-charging stage when the voltage of the battery 10 is determined to be less than the constant current threshold voltage V_{L}. During the pre-charging stage, the charging management chip 20 controls the battery 10 to be charged with small current. As shown in FIG. 2, in the pre-charging stage, as the charging progresses, the voltage Vd of the battery 10 gradually rises.

When the voltage Vd of the battery 10 rises to be greater than or equal to the constant current threshold voltage V_{L}, that is, when the charging management chip 20 determines that the voltage Vd of the battery 10 is greater than or equal to the constant current threshold voltage V_{L}, the battery 10 is controlled to enter the constant current charging stage. In the constant current charging stage, the charging management chip 20 controls a constant large current to output for charging the battery 10. Similarly, as shown in FIG. 2, as the charging progresses, the voltage Vd of the battery 10 continues to rise gradually.

When the voltage Vd of the battery 10 rises to be greater than or equal to the adjusted constant voltage threshold voltage Vc, that is, when the charging management chip 20 determines that the voltage Vd of the battery 10 is greater than or equal to the adjusted constant voltage threshold voltage Vc, the battery 10 is controlled to enter the constant voltage charging stage.

Since the adjusted constant voltage threshold voltage Vc is equal to the sum of the initial constant voltage threshold voltage Vc1 and the divided voltage Vf of the charging path impedance circuit 35, with respect to the existing charging control, when the voltage Vd of the battery 10 is determined to rise to the initial constant voltage threshold voltage Vc1, the charging management chip 20 controls the battery 10 to enter the constant voltage charging stage. In embodiments of the present disclosure, the constant current charging stage may be maintained for a longer period, that is, a time duration of charging at large current is longer, which increases a charging speed. In addition, when the voltage Vbat of the battery cell 11 rises to the initial constant voltage threshold voltage Vc1, the voltage Vd of the battery 10 will rise to Vc1+Vf, the battery 10, triggered by the charging management chip 20, may be switched to the constant voltage charging stage. Therefore, during the constant current charging stage, the voltage of the battery cell 11 is maintained below the initial constant voltage threshold voltage Vc1, which does not increase a charging risk of the battery 10.

In the constant voltage charging stage, the charging management chip 20 controls a constant charging voltage Vic to be output to charge the battery 10. Since the voltage Vd of the battery 10 gradually rises, the difference between the voltage Vd of the charging voltage Vic and the battery 10 is smaller and smaller. In the case where the overall resistance value of battery 10 remains unchanged, as shown in FIG. 2, during the constant voltage charging stage, the current Id of battery 10 will gradually decrease. The voltage Vd of the battery 10 gradually rises with slower rising speed. Therefore, in the constant voltage charging stage, as shown in FIG. 2, the voltage Vd of the battery 10 can also be approximately regarded as a constant voltage.

When the current Id of the battery 10 is reduced to be less than or equal to the cutoff critical current Ij, that is, when the charging management chip 20 determines that the current Id of the battery 10 is less than or equal to the cutoff critical current Ij, the charging management chip 20 controls the battery 10 to be charging cutoff, that is, stops charging the battery 10.

As shown in FIG. 1, the battery 10 includes a positive terminal 101 and a negative terminal 102. The charging management chip 20 is coupled to the positive terminal 101 and the negative terminal 102 of the battery 10 for providing the charging voltage Vic and the charging current Ic for the battery 10. The charging management chip 20 determines the voltage Vd of the battery 10 by detecting the voltage of the positive terminal 101 of the battery 10. As battery 10 is coupled in series to the charging management chip 20, the charging current Ic is the current output by the charging management chip 20 and is equal to the current of the battery 10, so the charging management chip 20 can determine the current Id of the battery 10 according to the output charging current Ic.

As shown in FIG. 1, the charging path impedance circuit 35 includes a battery internal circuit 36 located in the battery 10 and a connection circuit 37 outside the battery 10. The connection circuit 37 includes a connection line, a flexible circuit board, and/or a PCB trace located between the battery 10 and the charging management chip. In some embodiments, the connection circuit 37 is located between the negative electrode 102 of the battery 10 and the charging management chip 20, and the connection circuit 37 can be equivalent to a resistor R0.

As shown in FIG. 1, the battery 10 further includes a protection module 13 for detecting a temperature of the battery cell 11 and a voltage Vbat and a current Id of the battery cell 11, and generates a protection signal when the battery cell 11 is determined to be over-temperature, over-voltage, or over-current.

As shown in FIG. 1, the battery internal circuit 36 includes a discharge path switch 121 and a charging path switch 122. The discharge path switch 121 and the charging path switch 122 are coupled in series to a current loop of the battery cell 11. Specifically, the discharge path switch 121 and the charging path switch 122 are coupled in series between the negative electrode of the battery cell 11 and the ground.

The protection module 13 is coupled to the discharge path switch 121 and the charging path switch 122. When the battery cell 11 is over-temperature, over-voltage, or over-current and the battery 10/battery cell 11 is in a discharged state, the protection module 13 outputs the protection signal to the discharge path switch 121 to control the discharge path switch 121 to be cut off Thus, the current loop of the battery 10 is cutoff, and the battery 10 stops discharging.

When the battery cell 11 is over-temperature, over-voltage or over-current and the battery 10/battery cell 11 is in a charging state, the protection module 13 outputs a protection signal to the charging path switch 122 to control the cutting path switch 122 to be cut off. Similarly, the current loop of the battery 10 is cutoff, and the battery 10 stops charging.

In some embodiments, as shown in FIG. 1, the discharge path switch 121 is a first MOS transistor Q1, and the charging path switch 122 is a second MOS transistor Q2. The protection module 13 includes a first output pin 131 and a second output pin 132.

The gate of the first MOS transistor Q1 is electrically coupled to the first output pin 131 of the protection module 13, the source is electrically coupled to the battery cell 11, and the drain is electrically coupled to the drain of the MOS transistor Q2. The gate of the second MOS transistor Q2 is electrically coupled to the second output pin 131 of the protection module 13, and the source is coupled to the ground.

As shown in FIG. 1, the first MOS transistor Q1 and the second MOS transistor Q2 are NMOS transistors. The protection signal output by the protection module 13 is a low level signal. When the battery cell 11 is determined to be over-temperature, over-voltage or over-current and the battery 10/battery cell 11 is in the discharged state, the protection module 13 outputs a low level protection signal to the gate of the first MOS transistor Q1 through the first output pin 131 and the first MOS transistor Q1 is controlled to be cut off. When the battery cell 11 is determined to be over-temperature, over-voltage or over-current and the battery 10/battery cell 11 is in the charging state, the protection module 13 outputs a low level protection signal to the second MOS transistor Q2 through the second output pin 132 and the second MOS transistor Q2 is controlled to be cut off.

Obviously, when the protection module 13 determines that the battery cell 11 has not experienced any of over-temperature, over-voltage, and over-current, the first output pin 131 and the second output pin 132 are controlled to continuously output high power to maintain the conduction of the first MOS transistor Q1 and the second MOS transistor Q2

As shown in FIG. 1, the charging circuit 12 further includes a resistor R1, and the resistor R1, the charging path switch 121 and the discharge path switch 122 are coupled in series to the current loop of the battery cell 11. Specifically, the resistor R1 is coupled between a negative electrode of the battery cell 11 and the source of the first MOS transistor Q1. The resistor R1 can be a precision resistor.

The divided voltage Vf of the charging path impedance circuit 35 is equal to a sum of the voltages of the resistor R1, the first MOS transistor Q1, and the second MOS transistor Q2.

As shown in FIG. 1, the processor 30 includes two detecting pins 31. The two detecting pins 31 are coupled to positive and negative electrodes of the battery cell 11. The processor 30 determines the voltage Vbat of the battery cell 11 by detecting the difference between the voltages of the positive and negative electrodes of the battery cell 11.

In other embodiments, the processor 30 includes an I2C bus interface or an FPC connection interface. and the I2C bus interface or a connection interface of flexible circuit board (FPC) or the like of the processor 30 is coupled to the battery cell 11 through the I2C bus or the FPC. The processor 30 detects the voltage Vbat of the battery cell 11 through the I2C bus or the FPC or the like.

Where, the charging interface 40 can be a USB interface or the like. The charging power supply 200 may be a wired or wireless mains adapter coupled to a commercial power supply, or may be a USB interface power supply of a computer or the like.

The processor 30 can be a central processor, a micro processor, a micro controller, a single chip, a digital signal processor, and the like. The protection module 13 of the battery 10 can be a protection chip, and specifically can also be a micro control chip such as a single chip microcomputer, a micro processor, or a micro controller.

The electronic device 100 can be a device with a battery such as a mobile phone, a tablet computer, a notebook computer, a head mounted display device, or the like.

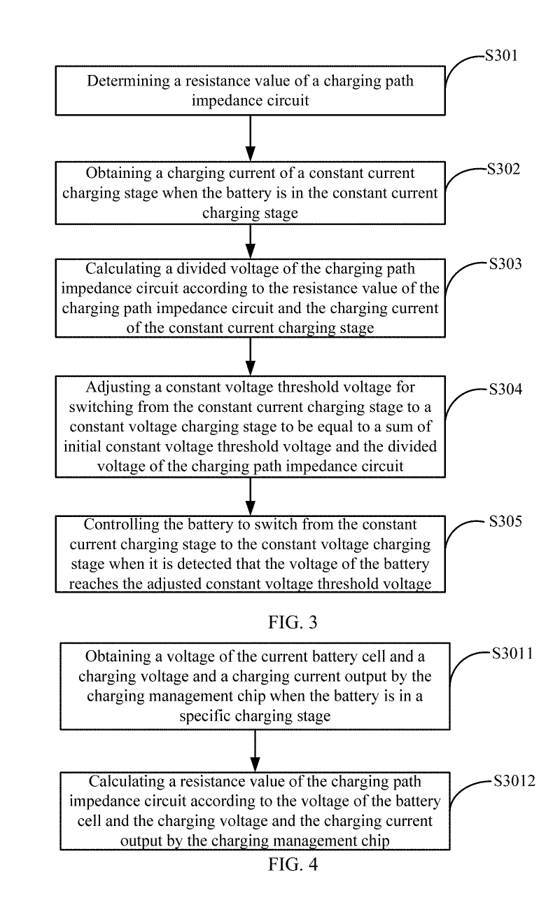

Referring to FIG. 3, a flowchart of a charging control method according to one embodiment of the present disclosure is illustrated. The method is applied to the aforementioned electronic device 100. The method includes the steps of:

The processor 30 determines a resistance value Rbat of the charging path impedance circuit 35 in the battery 10 (S301).

When the battery 10 is in a constant current charging stage, the processor 30 obtains a charging current Ic of the constant current charging stage (S302).

A divided voltage Vf of the charging path impedance circuit 35 is calculated according to the resistance value Rbat of the charging path impedance circuit 35 and the charging current Ic of the constant current charging stage (S303). Specifically, the divided voltage Vf of the charging path impedance circuit 35 is calculated according to a formula: Vf=Rbat*Ic.

A constant voltage threshold voltage Vc that switches the constant current charging stage to the constant voltage charging stage is adjusted to be equal to a sum of an initial constant voltage threshold voltage Vc1 and the divided voltage Vf of the charging path impedance circuit 35 (S304).

In some embodiments, the method further comprises the steps of:

When the battery 10 is in the constant current charging stage, the charging management chip 20 controls the battery 10 to switch from the constant current charging stage to the constant voltage charging stage when the voltage Vd of the battery 10 is detected to be reached the adjusted constant voltage threshold voltage Vc (S305).

In some embodiments, before step S301, the method further includes the step of: the charging management chip 20 detects the voltage of the battery 10 when the battery 10 is charging, and controls the battery 10 to enter a pre-charging stage when the voltage of the battery 10 is determined to be less than the constant current threshold voltage VL. During the pre-charging stage, the charging management chip 20 controls the battery 10 to be charged with small current.

In some embodiments, the method further includes the step of: the charging management chip 20 controls the battery 10 to enter the constant current charging stage when the voltage of the battery 10 is determined to be greater than or equal to the constant current threshold voltage VL. In the constant current charging stage, the charging management chip 20 controls a constant large current to be output to charge the battery 10.

In some embodiments, the method further includes the step of: the charging management chip 20 controls the battery 10 to enter the constant current charging stage when the voltage of the battery 10 is determined to be greater than or equal to the adjusted constant voltage threshold voltage Vc. In the constant current charging stage, the charging management chip 20 controls a constant voltage to be output to charge the battery 10.

In some embodiments, the method further includes the step of: when the battery 20 is charging, the charging management chip 20 detects the current Id of the battery 10, and stops charging the battery 10 when the current Id of the battery 10 is determined to be less than or equal to the cutoff critical current Ij during the constant voltage charging stage.

Referring to FIG. 4, a sub-flowchart of step S301 in one embodiment is illustrated. The step S301 specifically includes:

When the battery 10 is in a specific charging stage, the processor 30 obtains the current voltage Vbat of the battery cell 11 and the charging voltage Vic and the charging current Ic output by the charging management chip 20 (S3011).

The processor 30 calculates the resistance value Rbat of the charging path impedance circuit 35 according to the voltage Vbat of the battery cell 11 and the charging voltage Vic and the charging current Ic output by the charging management chip 20 (S3011). Specifically, the processor 30 calculates the resistance value Rbat of the charging path impedance circuit 35 according to the formula: Rbat=(Vic−Vbat)/Ic. The specific charging stage may be any one of the constant current charging stage, the pre-charging stage, and the constant voltage charging stage.

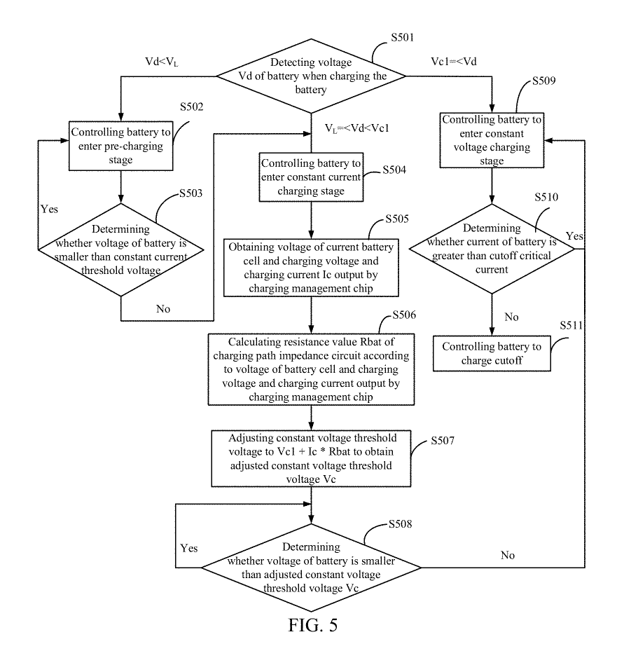

Referring to FIG. 5, a flowchart of a charging control method according to another embodiment of the present disclosure is illustrated. In another embodiment, the charging control method includes the steps of:

The charging control chip 20 detects the voltage Vd of the battery 10 when the battery 10 is charging (S501). When the voltage Vd of the battery 10 is detected to be less than the constant current threshold voltage VL, step S502 is performed. When the voltage Vd of the battery 10 is detected to be greater than or equal to the constant current threshold voltage VL and less than the initial constant voltage threshold voltage Vc1, step S504 is performed. When the voltage of the battery 10 is detected to be greater than or equal to the initial constant voltage threshold voltage Vc1, step S509 is performed.

The charge control chip 20 controls the battery 10 to enter the pre-charging stage (S502). Wherein, in the pre-charging stage, the charging management chip 20 controls the battery 10 to be charged with small current.

The charge control chip 20 determines whether the voltage Vd of the battery 10 is smaller than the constant current threshold voltage VL (S501). If yes, go back to step S502, if no, go to step S504.

The charge control chip 20 controls the battery 10 to enter the constant current charging stage (S504).

The processor 30 obtains the current voltage Vbat of the battery cell 11 and the charging voltage Vic and the charging current Ic output by the Charging management chip 20 (S505).

The processor 30 calculates the resistance value Rbat of the charging path impedance circuit 35 according to the voltage Vbat of the battery cell 11 and the charging voltage Vic and the charging current Ic output by the charging management chip 20 (S506).

The processor 30 adjusts the constant voltage threshold voltage Vc1 to Vc1+Ic*Rbat to obtain the adjusted constant voltage threshold voltage Vc (S507).

The charge control chip 20 determines whether the voltage Vd of the battery 10 is smaller than the adjusted constant voltage threshold voltage Vc (S508). If yes, go back to step S508, if no, go to step S509.

The charge control chip 20 controls the battery 10 to enter the constant voltage charging stage (S509).

The charge control chip 20 determines whether the current Id of the battery 10 is greater than the cutoff critical current Ij (S510). If yes, go back to step S509, if no, go to step S511.

The charge control chip 20 controls the battery 10 to charge cutoff (S511).

In the embodiment shown in FIG. 5, the resistance value Rbat of the charging path impedance circuit 35 is determined during the constant current charging stage. Obviously, as described above, in other embodiments, the resistance value Rbat of the charging path impedance circuit 35 can also be determined in any charging stage that is entered after battery 10 is turned on. For example, if the charging stage of the battery 10 is turned on and the charging stage is the pre-charging stage, the resistance value Rbat of the charging path impedance circuit 35 can be determined in the pre-charging stage.

According to the electronic device 100 and the charging control method of the present disclosure, the constant voltage threshold voltage Vc for switching the constant current charging stage to the constant voltage charging stage can be increased within an allowable range, so that the time duration of the constant current charging stage is longer, which increases the charging speed effectively.

The above is a preferred embodiment of the present disclosure, and it should be noted that those skilled in the art may make some improvements and modifications without departing from the principle of the present disclosure, and these improvements and modifications are also the protection scope of the present disclosure.

What is claimed is:

1. An electronic device, comprising a battery, a charging management chip, a charging path impedance circuit and a processor; the battery comprising a battery cell; the charging path impedance circuit located between the battery cell and the charging management chip; wherein, the processor is configured to determine a resistance value of the charging path impedance circuit, and obtain a charging current of a constant current charging stage when the battery is in the constant current charging stage, and calculate a divided voltage of the charging path impedance circuit according to the resistance value of the charging path impedance circuit and the charging current of the constant current charging stage; the processor is further configured to adjust a constant voltage threshold voltage for triggering switching of the battery from the constant current charging stage to a constant voltage charging stage to be equal to a sum of an initial constant voltage threshold voltage and the divided voltage of the charging path impedance circuit.

2. The electronic device according to claim 1, wherein, the processor obtains a voltage of the battery cell, a charging voltage and a charging current output by the charging management chip when the battery is in a specific charging stage; the processor calculates the resistance value of the charging path impedance circuit according to the voltage of the battery cell, the charging voltage and the charging current output by the charging management chip.

3. The electronic device according to claim 2, wherein, the processor calculates the resistance value Rbat of the charging path impedance circuit according to a formula Rbat=(Vic−Vbat)/Ic; Vic is the charging voltage output by the charging management chip; Vbat is the voltage of the battery cell; and Ic is the charging current output by the charging management chip.

4. The electronic device according to claim 2, wherein, the specific charging stage is one of the constant current charging stage, a pre-charging stage, and the constant voltage charging stage.

5. The electronic device according to claim 1, wherein, the charging management chip is further configured to detect a voltage of the battery when the battery is in the constant current charging stage, and determine whether the voltage of the battery reaches an adjusted constant voltage threshold voltage; when the voltage of the battery reaches the adjusted constant voltage threshold voltage, the charging management chip controls the battery to switch from the constant current charging stage to the constant voltage charging stage.

6. The electronic device according to claim 1, wherein, the charging management chip is further configured to detect the voltage of the battery when the battery is charging, and determine whether the voltage of the battery is less than a constant current threshold voltage; the charging management chip controls the battery to enter a pre-charging stage when the voltage of the battery is less than the constant current threshold voltage.

7. The electronic device according to claim 6, wherein, the charging management chip is further configured to control the battery to enter the constant current charging stage when the voltage of the battery is determined to be greater than or equal to the constant current threshold voltage.

8. The electronic device according to claim 5, wherein, the charging management chip is further configured to detect a current of the battery when the battery is charging, and stop charging the battery when the current of the battery is determined to be less than or equal to a cutoff critical current during the constant voltage charging stage.

9. The electronic device according to claim 6, wherein the battery comprises a positive terminal and a negative terminal; and the charging management chip is coupled to the positive terminal and the negative terminal of the battery, and provides a charging voltage and a charging current for the battery; the charging management chip determines the voltage of the battery by detecting a voltage of the positive terminal of the battery.

10. The electronic device according to claim 8, wherein, the current of the battery is equal to a charging current output by the charging management chip; and the charging management chip determines the current of the battery according to the charging current output by the charging management chip.

11. The electronic device according to claim 1, wherein, the battery further comprises a protection module configured to detect a temperature of the battery cell and a voltage and a current of the battery cell, and generate a protection signal when the battery cell is determined to be over-temperature, over-voltage or over-current.

12. The electronic device according to claim 11, wherein, the charging circuit comprises a charging path switch and a discharge path switch; the charging path switch and the discharging path switch are coupled in series to a current loop of the battery cell; the protection module is coupled to the charging path switch and the discharge path switch, and is configured to output the protection signal to the charging path switch and cut off the protection path switch when the battery cell is over-temperature, over-voltage or over-current, and the battery/battery cell is in a charging state; the protection module is further configured to output the protection signal to the discharge path switch and cut off the discharge path switch when the battery cell is over-temperature, over-voltage or over-current, and the battery/battery cell is in a discharged state.

13. A charging control method, applied to an electronic device comprising a battery, which comprises a battery cell and a charging circuit, wherein, the method comprises:
determining a resistance value of a charging path impedance circuit of the battery;
obtaining a charging current of a constant current charging stage when the battery is in the constant current charging stage;
calculating a divided voltage of the charging path impedance circuit according to the resistance value of the charging path impedance circuit and the charging current of the constant current charging stage; and
adjusting a constant voltage threshold voltage for triggering switching of the battery from the constant current charging stage to a constant voltage charging stage to be equal to a sum of an initial constant voltage threshold voltage and the divided voltage of the charging path impedance circuit.

14. The charging control method according to claim 13, wherein, the step of “determining a resistance value of a charging path impedance circuit of the battery” comprises:
obtaining a voltage of the battery cell, a charging voltage, and a charging current output by the charging management chip output when the battery is in a specific charging stage;
calculating the resistance value of the charging path impedance circuit according to the voltage of the battery cell, the charging voltage, the charging current output by the charging management chip.

15. The charging control method according to claim 14, wherein, the step of “calculating the resistance value of the charging path impedance circuit according to the voltage of the battery cell, the charging voltage, the charging current output by the charging management chip” comprises:
calculating the resistance value Rbat of the charging path impedance circuit according to a formula Rbat=(Vic−Vbat)/Ic; Vic is the charging voltage output by the charging management chip; Vbat is the voltage of the battery cell; and Ic is the charging current output by the charging management chip.

16. The charging control method according to claim 14, wherein, the specific charging stage is one of the constant current charging stage, a pre-charging stage, and the constant voltage charging stage.

17. The charging control method according to claim 13, wherein, the method further comprises the steps of:
detecting a voltage of the battery when the battery is in the constant current charging stage, and determining whether the voltage of the battery reaches an adjusted constant voltage threshold voltage;
controlling the battery to switch from the constant current charging stage to the constant voltage charging stage when the voltage of the battery reaches the adjusted constant voltage threshold voltage.

18. The charging control method according to claim 13, wherein, the method further comprises the steps of:
detecting a voltage of the battery when the battery is charging;
determining whether the voltage of the battery is less than a constant current threshold voltage;
controlling the battery to enter pre-charging stage when the voltage of the battery is less than the constant current threshold voltage.

19. The charging control method according to claim 18, wherein, the method further comprises the steps of:
controlling the battery to enter the constant current charging stage when the voltage of the battery is determined to be greater than or equal to the constant current threshold voltage.

20. The charging control method according to claim 17, wherein, the method further comprises the steps of:
detecting a current of the battery when the battery is charging, and stopping charging the battery when the current of the battery is determined to be less than or equal to a cutoff critical current during the constant voltage charging stage.
